(19) United States
(12) Patent Application Publication
(10) Pub. No.: US 2008/0048732 A1
(43) Pub. Date: Feb. 28, 2008

(54) Abnormality detection circuit

(76) Inventor: Takashi Oki, Ukyo-Ku (JP)

Correspondence Address: CANTOR COLBURN, LLP, 20 Church Street, 22nd Floor, Hartford, CT, 06103, US

(21) Appl. No.: 11/880,506

(22) Filed: Jul. 23, 2007

(30) Foreign Application Priority Data
Jul. 21, 2006 (JP) JP2006-199810

(51) Int. Cl. H02H 1/00; H03F 1/00; H03F 3/217; H03K 5/19

(52) U.S. Cl. 327/77

(57) ABSTRACT

An abnormality detection circuit monitors a power supply voltage and, when the power supply voltage drops, outputs an abnormality detection signal of a predetermined level. The source of a detection transistor as a P-channel MOSFET is connected to a power supply line to which a power supply voltage to be monitored is applied. A detection resistor as an impedance element is provided between the drain of the detection transistor and a ground terminal. A capacitor is provided between the gate of the detection transistor and the ground terminal. A charging path is provided between the gate of the detection transistor and the power supply line. The abnormality detection circuit outputs a drain voltage of the detection transistor as an abnormality detection signal.

### BACKGROUND OF THE INVENTION

1. Field of the Invention

The present invention relates to a technique for detection circuit abnormality and, more particularly, to an abnormality detection circuit for detecting a drop in a power supply voltage.

2. Description of the Related Art

With development in the LSI technique in recent years, a one-bit DAC (Digital Analog Converter) is used for digital signal process and amplification in digital audio equipment typified by a CD player and an MD player. In the one-bit DAC, a sound signal undergoes noise shaping by using a ΔΣ modulator and the resultant signal is output as a one-bit PWM signal subjected to pulse width modulation (PWM).

The one-bit PWM signal is amplified to a predetermined level for driving a speaker as a load. For the amplification, a high-efficiency class D amplifier is used. The amplified one-bit PWM signal passes through a back-end low-pass filter to become an analog reproduction signal, and the analog reproduction signal is reproduced as sound from the speaker. For example, Japanese Patent Application No. 2001-223537 discloses a driver circuit for amplifying a digital audio signal using a class D amplifier.

In such a class D amplifier, when the power supply voltage of the class D amplifier suddenly drops due to sudden pull-out of the plug, noise called “pop noise sound” is generated from the speaker. Japanese Patent Application No. 2001-223537 discloses a mute transistor for suppressing the noise.

To suppress pop noise sound effectively in such circumstances, it is necessary to promptly detect a drop in the power supply voltage and perform mute process.

### SUMMARY OF THE INVENTION

The present invention has been achieved in view of the problems and a general purpose of the invention is to provide an abnormality detection circuit capable of promptly detecting a drop in power supply voltage.

To solve the problem, according to an embodiment of the present invention, an abnormality detection circuit that monitors a power supply voltage and, when the power supply voltage drops, outputs an abnormality detection signal of a predetermined level is provided. The abnormality detection circuit includes: a P-channel MOSFET (Metal Oxide Semiconductor Field Effect Transistor) whose source is connected to a power supply line to which a power supply voltage to be monitored is applied; an impedance element provided between a drain of the P-channel MOSFET and a fixed voltage terminal; a capacitor provided between a gate of the P-channel MOSFET and the fixed voltage terminal; and a charging path provided between the gate of the P-channel MOSFET and the power supply line. A drain voltage of the P-channel MOSFET is output as the abnormality detection signal.

In this embodiment, in a normal operation in which the power supply voltage is stably supplied, the capacitor connected to the gate of the P-channel MOSFET is charged via the charging path, and the gate of the P-channel MOSFET is fixed to a potential lower than the power supply voltage by a predetermined voltage. The predetermined voltage is set to be larger than a threshold voltage Vt of the P-channel MOSFET. In this case, in the normal operation, the P-channel MOSFET is turned on, and the abnormality detection signal as the drain voltage becomes the high level. When the power supply voltage to be monitored, that is, the source voltage of the P-channel MOSFET drops suddenly, since the gate voltage of the P-channel MOSFET is maintained at a constant value, the gate-source voltage becomes lower than the threshold voltage Vt, the P-channel MOSFET is turned off, and the abnormality detection signal becomes low level. As described above, the abnormality detection circuit can instantaneously detect a drop in the power supply voltage.

The abnormality detection circuit in an embodiment may further include a discharging resistor connected in parallel with the capacitor. In this case, the gate voltage of the P-channel MOSFET can be stabilized to a voltage at which discharging by the discharging resistor and charging by the charging path are balanced. The time constant of an RC circuit constructed by the discharging resistor and the capacitor can be adjusted by the discharging resistor.

The charging path may include a charging diode whose cathode is connected to the gate side of the P-channel MOSFET and whose anode is connected to the source side of the P-channel MOSFET.

The abnormality detection circuit in an embodiment may further include, in a path parallel with the charging path, a discharging diode whose cathode is connected to the power supply line side and whose anode is connected to the gate side of the P-channel MOSFET.

In this case, when the power supply voltage, that is, the source voltage of the P-channel MOSFET drops and becomes below the gate voltage, charges can be discharged from the gate to the source via the discharging diode.

The charging path may include a charging resistor. In this case, by adjusting the resistance value of the charging resistor, the threshold value at which the level of the abnormality detection signal changes can be adjusted.

In an embodiment, the P-channel MOSFET may be replaced with a PNP-type bipolar transistor whose base, emitter, and collector are connected as the gate, source, and drain of the MOSFET, respectively. In this embodiment, also in the case of using bipolar process, detection of abnormality in the power supply can be realized.

According to another embodiment of the present invention, an audio signal amplifying circuit is provided. The audio signal amplifying circuit includes: a class D amplifier including two transistors connected in series between a power supply line to which a power supply voltage is applied and a fixed voltage terminal and turned on/off alternately; a pulse modulator that performs pulse modulation on an analog audio signal and generates a pulse signal; a driver circuit that drives the class D amplifier on the basis of the pulse signal; an abnormality detection circuit of the above-described embodiment, that monitors the power supply voltage; and a control circuit that fixes logical level of an input signal of the driver circuit when an abnormality detection signal of the predetermined level is output from the abnormality detection circuit.

In the another embodiment, when the power supply voltage supplied to the class D amplifier drops suddenly, the abnormal state can be detected by the abnormality detection circuit. An input of the driver circuit is fixed immediately and muting can be performed, so that occurrence of noise can be prevented.

The audio signal amplifying circuit may be integrated on a single semiconductor substrate. “Integration” includes the case where all of components of the circuit are formed on the semiconductor substrate and the case where main components of the circuit are integrated. For adjustment of the circuit constant, a resistor, a capacitor, and the like as a part of the components may be provided on the outside of the semiconductor substrate. By integrating the audio signal amplifying circuit as a single LSI, the circuit area can be reduced and the characteristics of the circuit elements can be maintained uniformly.

Further another embodiment of the invention is electronic equipment. The electronic equipment includes: a sound reproducing unit that generates an analog audio signal; an audio signal amplifying circuit as in the above-described embodiment that amplifies an analog audio signal output from the sound reproducing unit; and a sound output unit driven by the audio signal amplifying circuit.

In this embodiment, also in the case where abnormality occurs in the power supply voltage, occurrence of noise from the sound output unit such as a speaker and an earphone can be suppressed.

It is to be noted that any arbitrary combination or rearrangement of the above-described structural components and so forth is effective as and encompassed by the present embodiments.

Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a circuit diagram showing the configuration of an abnormality detection circuit according to an embodiment of the present invention;

FIG. 2 is an operation waveform chart of the abnormality detection circuit of FIG. 1;

FIG. 3 is a circuit diagram showing the configuration of an audio signal amplifying circuit using the abnormality detection circuit of FIG. 1; and

FIG. 4 is a block diagram showing the configuration of electronic equipment in which the audio signal amplifying circuit of FIG. 3 is mounted.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

In the specification, the expression that “a member A and a member B are connected to each other” includes the case where the members A and B are physically directly connected to each other and the case where the members A and B are indirectly connected to each other via another member which does not exert an influence on an electric connection state.

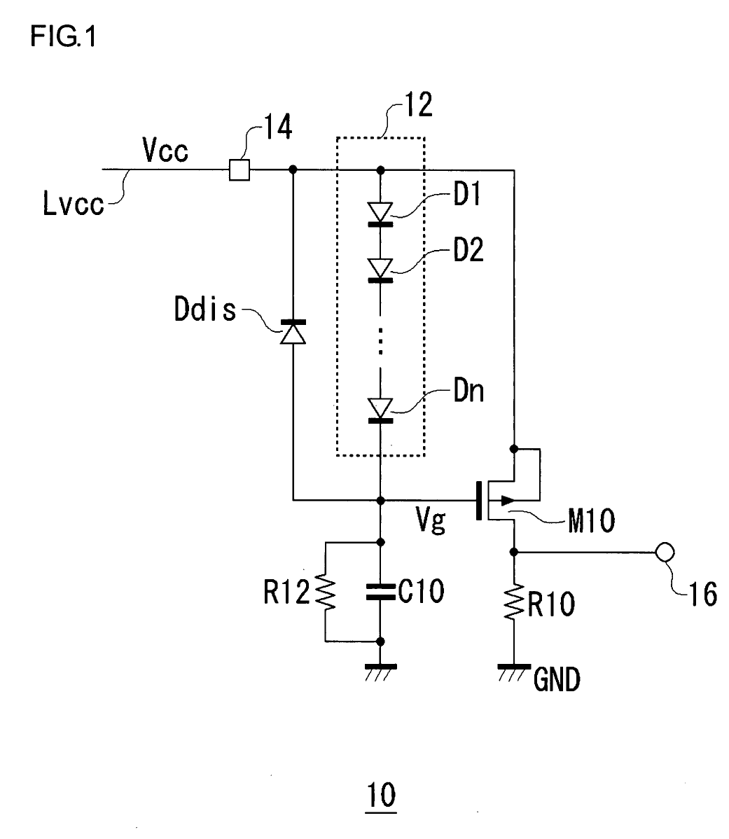

FIG. 1 is a circuit diagram showing the configuration of an abnormality detection circuit 10 according to an embodiment of the invention. The abnormality detection circuit 10 monitors a power supply voltage Vcc input to a monitor terminal 14 and outputs an abnormality detection signal Sabn which becomes a predetermined level (low level) when the power supply voltage Vcc drops. The abnormality detection circuit 10 has a detection transistor M10, a detection resistor R10, a capacitor C10, a discharging resistor R12, a charging path 12, and a discharging diode Ddis.

The monitor terminal 14 is connected to a power supply line Lvcc to which the power supply voltage Vcc is applied. The detection transistor M10 is a P-channel MOSFET and its source is connected to the power supply line Lvcc to which the power supply voltage Vcc to be monitored is applied via the monitor terminal 14.

The detection resistor R10 is an impedance element provided between the drain of the detection transistor M10 and a ground terminal GND as a fixed voltage terminal. The detection resistor R10 may be constructed by an impedance element having a significant impedance component such as a resistor and a biased transistor.

The capacitor C10 is provided between the gate of the detection transistor M10 and the ground terminal GND. The discharging resistor R12 is connected in parallel with the capacitor C10. The charging path 12 is provided between the gate of the detection transistor M10 and the power supply line Lvcc. The charging path 12 includes “n” pieces of charging diodes D1 to Dn whose cathodes are connected to the gate side of the detection transistor M10 and whose anodes are connected to the source side of the detection transistor M10.

The abnormality detection circuit 10 further includes the discharging diode Ddis in a path parallel with the charging path 12, that is, between the gate and the source of the detection transistor M10 so that the cathode is connected on the power supply line Lvcc side and the anode is connected on the gate side of the detection transistor M10. In the case where the power supply voltage Vcc decreases and becomes lower than a gate voltage Vg of the detection transistor M10, the discharging diode Ddis can discharge the charges accumulated in the capacitor C10 toward the power supply line Lvcc via the discharging diode Ddis.

The abnormality detection circuit 10 outputs the drain voltage of the detection transistor M10 as the abnormality detection signal Sabn from an output terminal 16.

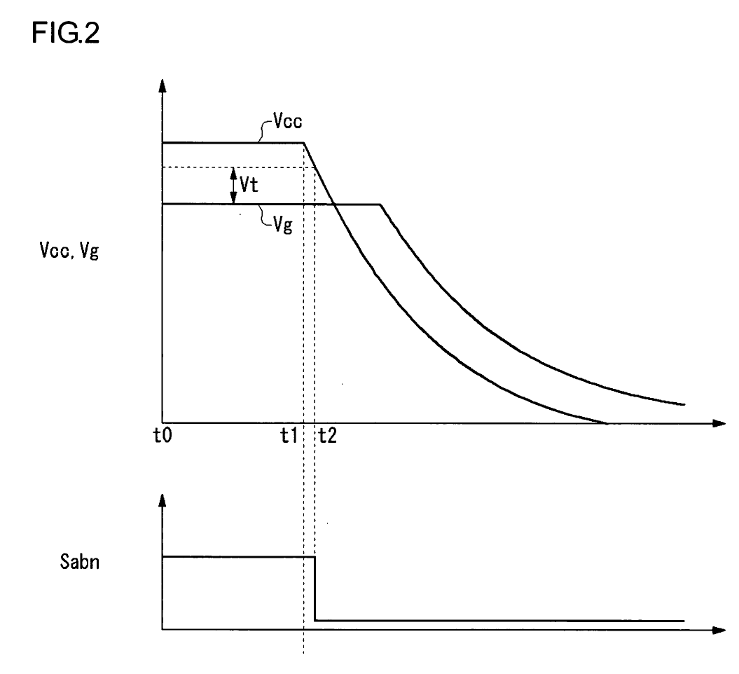

The operation of the abnormality detection circuit 10 having the above configuration will be described. FIG. 2 is an operation waveform chart of the abnormality detection circuit 10. A period from time t0 to time t1 is a normal operation period. FIG. 2 shows the power supply voltage Vcc, the gate voltage Vg of the detection transistor M10, and the abnormality detection signal Sabn.

In the period from time t0 to time t1, the predetermined power supply voltage Vcc is stably supplied to the power supply line Lvcc. At this time, the capacitor C10 is charged by the charging path 12, and the gate voltage Vg of the detection transistor M10 maintains a predetermined value. The number “n” of the charging diodes D1 to Dn in the charging path 12 is set so that gate-source voltage Vgs=Vcc−Vg of the detection transistor M10 in the normal operation becomes larger than a threshold voltage Vt of the detection transistor M10. The detection transistor M10 is turned on, the drain of the detection transistor M10 becomes almost equal to the power supply voltage Vcc, and the abnormality detection signal Sabn becomes the high level indicating that no abnormality occurs.

The abnormality detecting operation will now be described. At time t1, the power supply voltage Vcc is interrupted. The interruption of the power supply voltage Vcc occurs in the case such that the user of electronic equipment on which the abnormality detection circuit 10 is mounted suddenly pulls out the socket. Generally, a stabilization capacitor which is not shown in FIG. 1 is connected to the power supply line Lvcc. Consequently, even when the plug is pulled out, the power supply voltage Vcc does not drop immediately but drops with a time constant.

When the power supply voltage Vcc is interrupted, charging of the capacitor C10 by the charging path 12 is also interrupted or weakened, so that the gate voltage Vg of the detection transistor M10 starts decreasing. On the other hand, since the capacitor C10 is provided between the gate of the detection transistor M10 and the ground terminal GND, the gate voltage Vg does not drop immediately but drops with an RC time constant determined by the capacitance value of the capacitor C10 and the resistance value of the discharging resistor R12. The RC time constant of the capacitor C10 and the discharging resistor R12 is desirably set to be lower than the drop speed of the power supply voltage Vcc when the power supply is interrupted. As a result, as shown in FIG. 2, the drop speed of the gate voltage Vg becomes lower than that of the power supply voltage Vcc. Consequently, the gate-source voltage Vgs=Vcc−Vg of the detection transistor M10 decreases with time. When the gate-source voltage Vgs becomes smaller than the threshold voltage Vt of the detection transistor M10 at time t2, the detection transistor M10 is turned off, and the abnormality detection signal Sabn becomes the low level.

As described above, in the abnormality detection circuit 10 of FIG. 1, by making the drop speed of the power supply voltage Vcc as the source voltage of the detection transistor M10 and that of the gate voltage Vg different from each other, when the power supply voltage Vcc is interrupted, the detection transistor M10 is turned off and, on the basis of the on/off state of the detection transistor M10, an abnormal state of the power supply voltage can be detected. The other circuit blocks can perform predetermined signal processes on the basis of the abnormality detection signal Sabn.

In the abnormality detection circuit 10 in FIG. 1, the detection transistor M10 may not be a P-channel MOSFET but maybe replaced with a PNP-type bipolar transistor. In this case, it is sufficient to make the base, emitter, and collector of the bipolar transistor correspond to the gate, source, and drain of the MOSFET, respectively.

In the abnormality detection circuit 10 in FIG. 1, the charging path 12 is constructed by “n” pieces of the charging diodes D1 to Dn. Alternatively, the charging path 12 may be constructed by resistors. In the case of constructing the charging path 12 by a resistor, by adjusting the resistance value of the resistor, the gate voltage Vg of the detection transistor M10 in the normal operation can be easily adjusted. In this case, the resistor may be an external part of the LSI. The charging path 12 may be constructed by a combination of a diode and a resistor.

An example of a preferable application of the abnormality detection circuit 10 will now be described. The abnormality detection circuit 10 is applied to a signal amplifying circuit for amplifying an audio signal and supplying the amplified audio signal to a sound output unit such as a speaker.

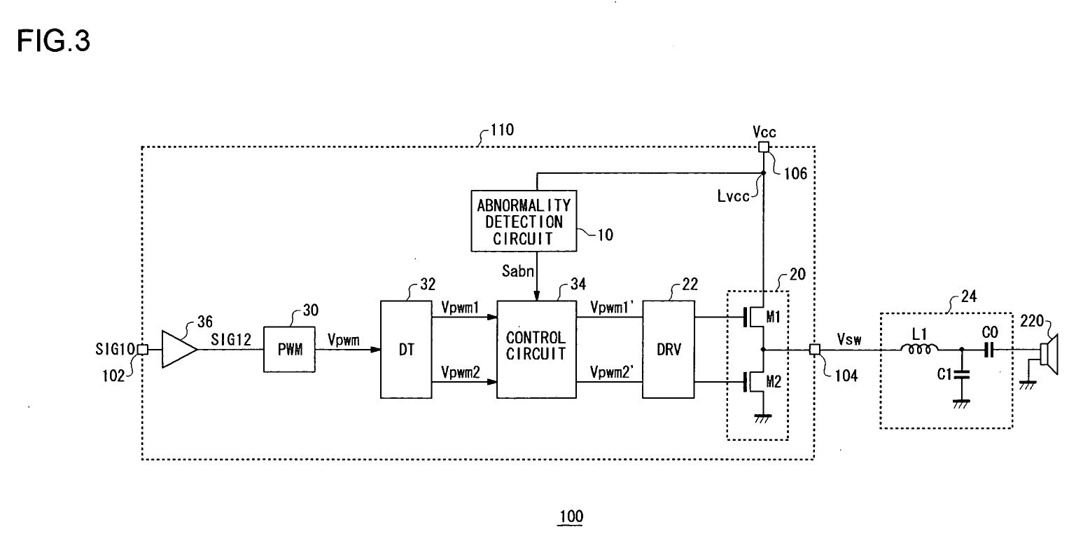

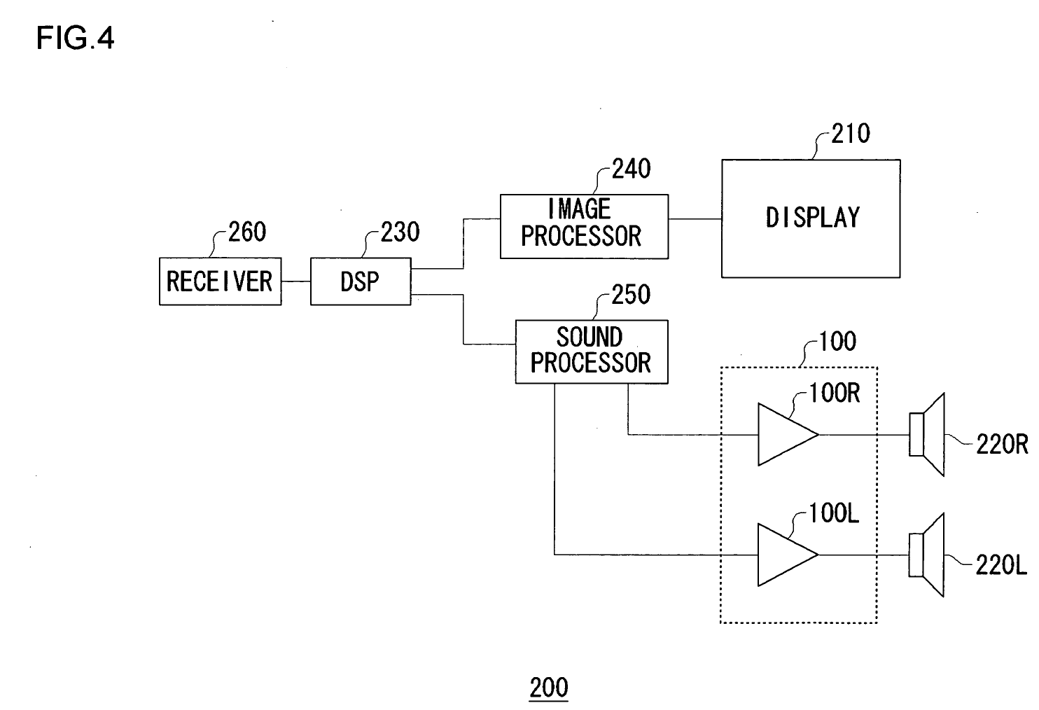

FIG. 3 is a circuit diagram showing the configuration of an audio signal amplifying circuit 100 of the embodiment. FIG. 4 is a block diagram showing the configuration of electronic equipment 200 on which the audio signal amplifying circuit 100 of FIG. 3 is mounted. In the embodiment, the electronic equipment 200 is a television receiver. The electronic equipment 200 includes a display 210 such as a cathode ray tube or a liquid crystal panel, speakers 220R and 220L, a DSP (Digital Signal Processor) 230, an image processor 240, a sound processor 250, the audio signal amplifying circuit 100, and a receiver 260.

The receiver 260 is a tuner or the like which detects and amplifies a broadcast wave supplied from a not-shown antenna and outputs the amplified signal to the DSP 230. The DSP 230 demodulates the signal output from the receiver 260, outputs data of an image to the image processor 240, and outputs data of sound to the sound processor 250. The DSP 230 is a core block for controlling the entire electronic equipment 200 in a centralized manner. The image processor 240 includes a display driver and the like, performs a necessary signal process on image data, and displays an image and a video image on the display 210 scanning line by scanning line. The receiver 260 may be a unit for receiving a signal output from a VTR (Video Tape Recorder), a DVD player, or the like.

The sound processor 250 performs a predetermined signal process on an audio signal output from the DSP 230 and outputs the processed signal to the audio signal amplifying circuit 100. When the audio signal is a stereo signal, the audio signal is divided into a right channel and a left channel. The audio signal amplifying circuit 100 includes two audio signal amplifying circuits 100R and 100L for the right and left channels. The audio signal amplifying circuits 100R and 100L amplify the audio signal and output the amplified signal to the speakers 220R and 220L. The audio signal amplifying circuit 100 of the embodiment is mounted on such electronic equipment 200.

When the user turns on the power of the electronic equipment 200, the DSP 230 performs initializing process. The DSP 230 initializes the blocks such as the image processor 240 and the audio signal amplifying circuit 100.

Referring again to FIG. 3, the audio signal amplifying circuit 100 includes an audio LSI 110 having a class D amplifier therein, and a filter 24.

The audio LSI 110 is a semiconductor integrated circuit for converting an input analog audio signal SIG10 to a pulse width modulation signal having a duty ratio according to the amplitude of the analog audio signal SIG10 and outputting the pulse width modulation signal. The audio LSI 110 has, as input/output terminals, an input terminal 102, an output terminal 104, and a power supply terminal 106. To the input terminal 102, the analog audio signal SIG10 output from the sound processor 250 in FIG. 4 is input. The output terminal 104 is connected to the filter 24 and outputs a pulse-width-modulated switching voltage Vsw.

The filter 24 is a low-pass filter including an inductor L1, a first capacitor C1, and an output capacitor C0 and eliminating high frequency components of the switching voltage Vsw output from the audio LSI 110. The output capacitor C0 is a DC block capacitor for preventing direct current from flowing in the speaker 220. From the switching voltage Vsw output from the audio LSI 110, the high frequency components are removed by the filter 24, thereby converting the pulse-width-modulated signal to an analog audio signal.

Next, the configuration of the audio LSI 110 will be described. The audio LSI 110 includes a class D amplifier 20, a driver circuit 22, a pulse width modulator 30, a dead time generator 32, a control circuit 34, and an amplifier 36.

The analog audio signal SIG10 input to the input terminal 102 is input to the amplifier 36. The DC level of the amplifier 36 is set to the middle point Vcc/2 (hereinbelow, called middle point level) of the power supply voltage Vcc and the ground potential. The amplifier 36 amplifies the analog audio signal SIG10 and outputs a signal superimposed on the middle point level Vcc/2. An output signal of the amplifier 36 is called an analog audio signal SIG12.

An anti-aliasing filter (not shown) for preventing aliasing noise by eliminating signals equal to or higher than the Nyquist frequency is provided at the front stage or rear stage of the amplifier 36 or integrally with the amplifier 36.

The pulse width modulator 30 converts the analog audio signal SIG12 to a pulse width modulation signal Vpwm. The pulse width modulator 30 generally includes an oscillator and a comparator. The oscillator generates a triangluar wave or sawtooth wave periodic voltage. The comparator compares the periodic voltage with the analog audio signal SIG12, and outputs the pulse width modulation signal Vpwm. The duty ratio of the pulse width modulation signal Vpwm changes according to the analog audio signal SIG12.

The deadtime generator 32 generates dead time in which first and second MOS transistors M1 and M2 are not simultaneously turned on. For example, the dead time generator 32 generates a first pulse width modulation signal Vpwm1 obtained by delaying the negative edge of the pulse width modulation signal Vpwm by predetermined time and inverting the logic and a second pulse width modulation signal Vpwm2 obtained by delaying the positive edge of the pulse width modulation signal Vpwm by predetermined time and inverting the logic. Since it is sufficient to use the existing technique for generating dead time, the description will not be given.

The driver circuit 22 drives the class D amplifier 20 on the basis of the pulse width modulation signal Vpwm output from the pulse width modulator 30. The class D amplifier 20 includes a first MOS transistor Ml of the P channel and a second MOS transistor M2 of the N channel connected in series between the power supply line Lvcc and the ground terminal GND. When the pulse width modulation signal Vpwm is at the low level, the driver circuit 22 turns on the first MOS transistor M1 and turns off the second MOS transistor M2. When the pulse width modulation signal Vpwm is at the high level, the driver circuit 22 turns off the first MOS transistor M1 and turns on the second MOS transistor M2. The first MOS transistor M1 may be constructed by an N-channel MOSFET.

The abnormality detection circuit 10 monitors the power supply voltage Vcc supplied via the power supply terminal 106. The abnormality detection circuit 10 has been described above. The abnormality detection circuit 10 outputs the abnormality detection signal Sabn which becomes the low level when the power supply voltage Vcc drops. The abnormality detection signal Sabn is input to the control circuit 34.

The control circuit 34 is provided between the dead time generator 32 and the driver circuit 22. To the control circuit 34, in addition to the abnormality detection signal Sabn, the first pulse width modulation signal Vpwm1 and the second pulse width modulation signal Vpwm2 are input. When the low-level abnormality detection signal Sabn is output from the abnormality detection circuit 10, the control circuit 34 fixes the logic levels of the first and second pulse width modulation signals Vpwm1 and Vpwm2, and fixes the logic level of an input signal of the driver circuit 22.

The operation of the audio signal amplifying circuit 100 having the above construction will be described. When the plug of the electronic equipment 200 of FIG. 4 is pulled out, the power supply voltage Vcc supplied to the power supply terminal 106 drops suddenly. Immediately after the drop of the power supply voltage Vcc, the abnormality detection circuit 10 switches the abnormality detection signal Sabn to the low level. When the abnormality detection signal Sabn becomes the low level, the control circuit 34 fixes the logic level of an input signal to the driver circuit 22. When the logic level of the input signal to the driver circuit 22 is fixed, switching of the class D amplifier 20 stops, the switching voltage Vsw is fixed to the low level, and a mute state is set.

When the class D amplifier 20 operates, the average level of the input signal of the speaker 220 fluctuates as the power supply voltage Vcc drops. Therefore, when the power supply voltage Vcc changes suddenly, the level of the input signal of the speaker 220 also changes sharply, and noise occurs. In contrast, in the audio signal amplifying circuit 100 of the embodiment, a drop in the power supply voltage Vcc is immediately detected and the operation of the class D amplifier 20 is stopped. Thus, occurrence of noise in the speaker 220 can be suppressed preferably.

Although the logic level of a signal is fixed by the control circuit 34 in the embodiment, it is unnecessary to provide a mute circuit immediately before the speaker 220, and there is an advantage that the number of parts can be reduced. In addition to the control circuit 34, a mute circuit may be provided immediately before the speaker 220. The control circuit 34 is not limited to the position between the dead time generator 32 and the driver circuit 22 but may be disposed in any position as long as it can stop the operation of the class D amplifier 20 as a result.

The present invention has been described on the basis of the embodiment. It is understood by the person skilled in the art that the embodiment is illustrative, combinations of the components and processes can be variously modified, and the modifications are within the scope of the present invention. Such modifications will be described below.

In the embodiment, the case where the audio LSI 110 as one of components of the audio signal amplifying circuit 100 of FIG. 3 is integrated in a single semiconductor integrated circuit has been described. The invention is not limited to the case. The audio LSI 110 may be constructed as a plurality of LSIs.

The electronic equipment 200 on which the audio signal amplifying circuit 100 of the embodiment is mounted is not limited to the television receiver of FIG. 4 described in the embodiment but can be widely applied to a CD player, an audio amplifier, and the like.

Further, the application of the abnormality detection circuit 10 of the embodiment is not limited to the audio signal amplifying circuit using the class D amplifier but can be used for various signal processing circuits.

While the preferred embodiments of the present invention have been described using specific terms, such description is for illustrative purposes only, and it is to be understood that changes and variations may be made without departing from the spirit or scope of the appended claims.

What is claimed is:

1. An abnormality detection circuit that monitors a power supply voltage and, when the power supply voltage drops, outputs an abnormality detection signal of a predetermined level, comprising:
a P-channel MOSFET (Metal Oxide Semiconductor Field Effect Transistor) whose source is connected to a power supply line to which a power supply voltage to be monitored is applied;
an impedance element provided between a drain of the P-channel MOSFET and a fixed voltage terminal;
a capacitor provided between a gate of the P-channel MOSFET and the fixed voltage terminal; and
a charging path provided between the gate of the P-channel MOSFET and the power supply line, wherein a drain voltage of the P-channel MOSFET is output as the abnormality detection signal.

2. The abnormality detection circuit according to claim 1, further comprising a discharging resistor connected in parallel with the capacitor.

3. The abnormality detection circuit according to claim 1, wherein
the charging path includes a charging diode whose cathode is connected to the gate side of the P-channel MOSFET and whose anode is connected to the source side of the P-channel MOSFET.

4. The abnormality detection circuit according to claim 3, further comprising, in a path parallel with the charging path, a discharging diode whose cathode is connected to the power supply line side and whose anode is connected to the gate side of the P-channel MOSFET.

5. The abnormality detection circuit according to claim 1, wherein
the charging path includes a charging resistor.

6. The abnormality detection circuit according to claim 1, wherein
the P-channel MOSFET is replaced with a PNP-type bipolar transistor whose base, emitter, and collector are connected as the gate, source, and drain of the MOSFET, respectively.

7. An audio signal amplifying circuit comprising:
a class D amplifier including two transistors connected in series between a power supply line to which a power supply voltage is applied and a fixed voltage terminal and turned on/off alternately;
a pulse modulator that performs pulse modulation on an analog audio signal and generates a pulse signal;
a driver circuit that drives the class D amplifier on the basis of the pulse signal;
an abnormality detection circuit according to claim 1, that monitors the power supply voltage; and
a control circuit that fixes logical level of an input signal of the driver circuit when an abnormality detection signal of the predetermined level is output from the abnormality detection circuit.

8. The audio signal amplifying circuit according to claim 7, wherein
the circuit is integrated on a single semiconductor substrate.

9. Electronic equipment comprising:
a sound reproducing unit that generates an analog audio signal;
an audio signal amplifying circuit according to claim 7 that amplifies an analog audio signal output from the sound reproducing unit; and
a sound output unit driven by the audio signal amplifying circuit.
